(19) United States
(12) Patent Application Publication
(10) Pub. No.: US 2025/0055250 A1
(43) Pub. Date: Feb. 13, 2025

(54) LIGHT-EMITTING DEVICE

(71) Applicant: NICHIA CORPORATION, Anan-shi (JP)

(72) Inventor: Masatoshi NAKAGAKI, Komatsushima-shi (JP)

(21) Appl. No.: 18/791,226

(22) Filed: Jul. 31, 2024

(30) Foreign Application Priority Data
Aug. 8, 2023 (JP) 2023-129006

(51) Int. Cl. H01S 5/02208; H01S 5/02218; H01S 5/02255; H01S 5/02326

(52) U.S. Cl. CPC H01S 5/02208; H01S 5/02218; H01S 5/02255; H01S 5/02326

(57) ABSTRACT

A light-emitting device includes: a substrate made of a metal material and having an upper surface, the upper surface including a recessed portion, the recessed portion having a bottom surface including a flat region; a submount disposed on the bottom surface of the recessed portion; a semiconductor laser element disposed on the submount, and configured to emit a laser light; a lens support member disposed on the submount; a lens supported by the lens support member, and configured to collimate or converge the laser light emitted from the semiconductor laser element; and a frame body made of a ceramic material and surrounding the semiconductor laser element. In a top view, each of the substrate and the semiconductor laser element has a rectangular shape having long sides and short sides. The long sides of the substrate and the long sides of the semiconductor laser element are parallel to one another.

### CROSS-REFERENCE TO RELATED APPLICATION

This application claims priority to Japanese Patent Application No. 2023-129006, filed on Aug. 8, 2023, the disclosure of which is hereby incorporated by reference in its entirety.

### BACKGROUND

The present disclosure relates to a light-emitting device.

Light-emitting devices for emitting a laser light with the use of a semiconductor laser element can be used in devices such as laser processing machines, projectors, and light sources for lighting devices. In such light-emitting devices, due to errors in manufacture or structural deformation in the process of manufacture, heat radiated from a semiconductor laser element during operation cannot effectively transferred to the outside of the light-emitting device, and there is a probability that the heat will adversely affect the operation of the semiconductor laser element (for example, see Japanese Laid-Open Patent Publication No. 2002-231864).

### SUMMARY

In a light-emitting device configured to emit a laser light with the use of a semiconductor laser element, the heat radiated from the semiconductor laser element while the light-emitting device is in operation is demanded to be effectively transferred to the outside of the light-emitting device.

A light-emitting device of the present disclosure includes: a substrate having an upper surface, the upper surface including a recessed portion, the recessed portion having a bottom surface including a flat region, the substrate being made of a metal material; a submount disposed on the bottom surface of the recessed portion; a semiconductor laser element disposed on the submount, the semiconductor laser element being configured to emit a laser light; a lens support member disposed on the submount; a lens supported by the lens support member, the lens being configured to collimate or converge the laser light emitted from the semiconductor laser element; and a frame body surrounding the semiconductor laser element, the frame body being made of a ceramic material. In a top view, each of the substrate and the semiconductor laser element has a rectangular shape, the rectangular shape having long sides and short sides. The long sides of the substrate and the long sides of the semiconductor laser element are parallel to one another.

According to an embodiment of the present disclosure, the heat radiated from the semiconductor laser element while the light-emitting device is in operation can be effectively transferred to the outside of the light-emitting device.

### BRIEF DESCRIPTION OF THE DRAWINGS

FIG. 1A is a perspective view schematically illustrating the configuration of a light-emitting device according to an exemplary embodiment of the present disclosure.

FIG. 1B is an exploded perspective view of the light-emitting device illustrated in FIG. 1A.

FIG. 1C is another exploded perspective view of the light-emitting device illustrated in FIG. 1A.

FIG. 1D is a perspective view of a frame body included in the light-emitting device illustrated in FIG. 1A as viewed from below.

FIG. 1E is a top view of the configuration of the light-emitting device illustrated in FIG. 1A, in which a cover is not shown.

FIG. 1F is a cross-sectional view parallel to a YZ plane of the light-emitting device illustrated in FIG. 1A.

FIG. 1G shows a modification of the configuration illustrated in FIG. 1F, in which the upper surface of the substrate is partially modified.

FIG. 2A is a cross-sectional view parallel to the YZ plane, schematically illustrating the configuration of a variation example of the light-emitting device of the present embodiment.

FIG. 2B is a top view of the configuration of a base part for use in the light-emitting device illustrated in FIG. 2A.

FIG. 3A is a cross-sectional view parallel to the YZ plane for describing an example of a step in the production method of a base part for use in the light-emitting device of the present embodiment.

FIG. 3B is a cross-sectional view parallel to the YZ plane for describing an example of a step in the production method of a base part for use in the light-emitting device of the present embodiment.

FIG. 3C is a cross-sectional view parallel to the YZ plane for describing an example of a step in the production method of a base part for use in the light-emitting device of the present embodiment.

FIG. 4A is a cross-sectional view parallel to the YZ plane for describing an example of a step in the production method of a base part for use in a variation example of the light-emitting device of the present embodiment.

FIG. 4B is a cross-sectional view parallel to the YZ plane for describing an example of a step in the production method of a base part for use in a variation example of the light-emitting device of the present embodiment.

FIG. 5A is an exploded perspective view of a laser light source.

FIG. 5B is a cross-sectional view parallel to the YZ plane of the laser light source.

### DETAILED DESCRIPTION

Hereinafter, a light-emitting device according to certain embodiments of the present disclosure, a production method of a base part for use in the light-emitting device, and a manufacturing method of the light-emitting device are described with reference to the drawings. Parts designated with the same reference numerals appearing in multiple drawings indicate identical or equivalent parts.

The embodiment described below is exemplified to embody a technical idea of the present invention, and the present invention is not limited to the following. The descriptions of dimensions, materials, shapes, relative arrangements, and the like of components are not intended to limit the scope of the present invention thereto but intended to be illustrative. The size and positional relationship of members illustrated in the drawings may be exaggerated to facilitate understanding.

In the present description or the scope of claims, the term “polygon,” (which includes, e.g., triangles or quadrangles) includes shapes in which the corners of the polygons are rounded, chamfered, beveled, or coved. Not only a shape with modification at its corner (an end of a side), but also a shape with modification at an intermediate portion of a side thereof is referred to as a polygon. In other words, a polygon-based shape with partial modification is included in the interpretation of “polygon” described in the present description and the scope of claims.

### Embodiments

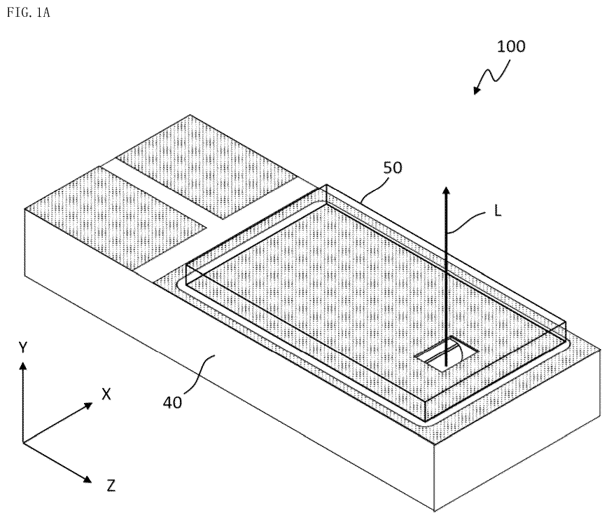

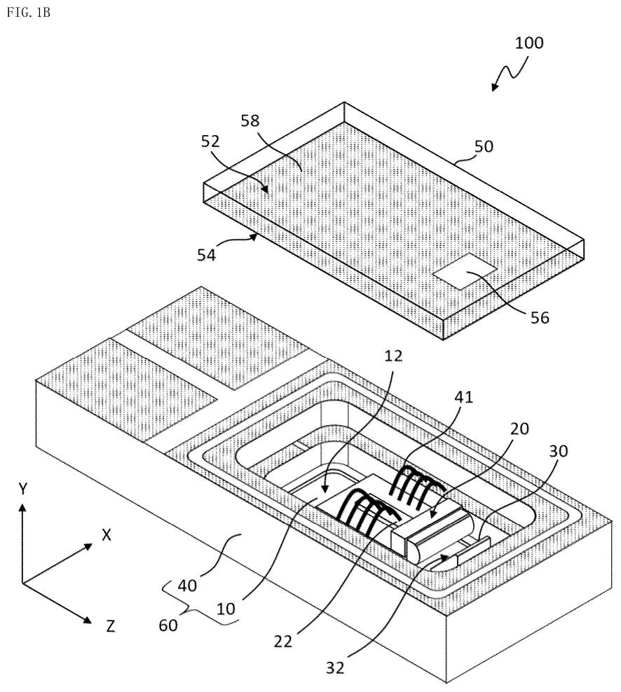

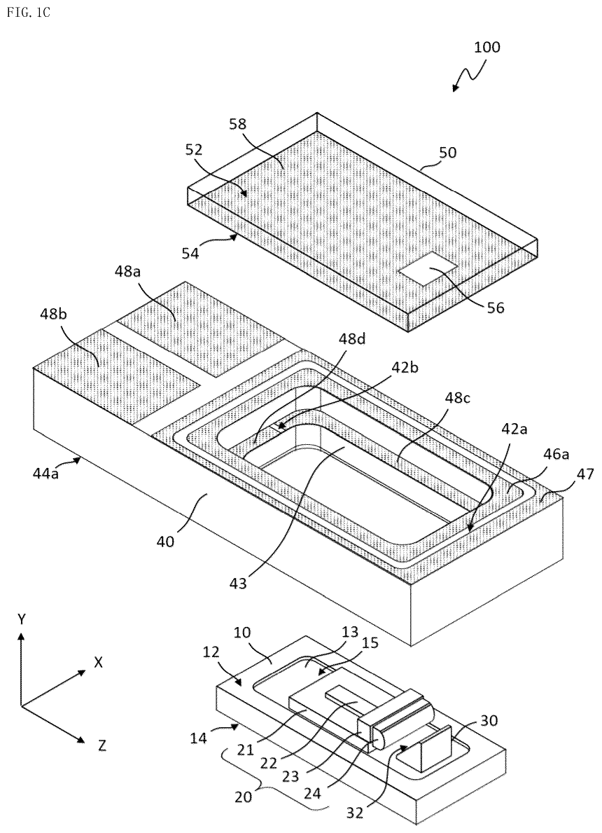

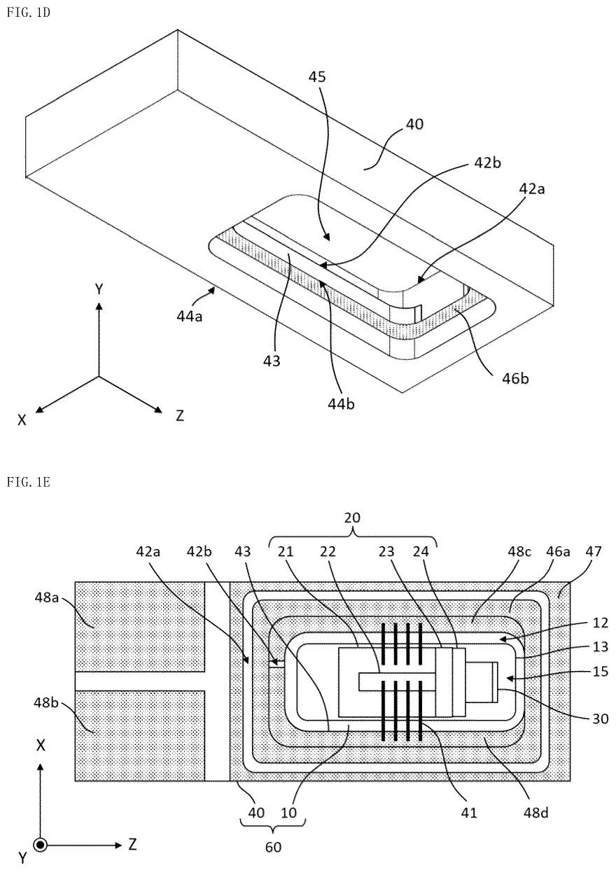

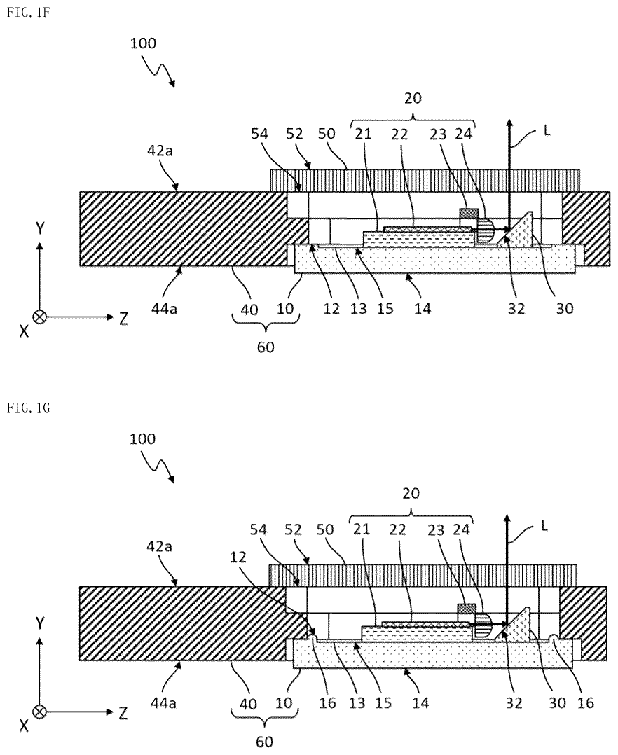

Hereinafter, a configuration example of a light-emitting device according to an embodiment of the present disclosure is described with reference to FIG. 1A and FIG. 1B. FIG. 1A is a perspective view schematically illustrating the configuration of a light-emitting device according to an exemplary embodiment of the present disclosure. FIG. 1B is an exploded perspective view of the light-emitting device illustrated in FIG. 1A. The light-emitting device 100 illustrated in FIG. 1A and FIG. 1B is configured such that a laser light L emitted from a semiconductor laser element located inside the light-emitting device 100 is irradiated to the outside of the light-emitting device 100.

The light-emitting device 100 includes a substrate 10, a laser light source 20, and a frame body 40 as illustrated in FIG. 1B. The light-emitting device 100 may further include a mirror member 30, a plurality of wires 41, and a cover 50. The substrate 10 has an upper surface 12. The laser light source 20 is a chip-on-submount semiconductor laser light source including a semiconductor laser element 22. The mirror member 30 has a reflective surface 32. The light-emitting device 100 may further include a protective element, such as a Zener diode, and/or a temperature measuring element for measuring an internal temperature, such as a thermistor. In this specification, a structure formed by bonding together the substrate 10 and the frame body 40 is also referred to as “base part 60”. The base part 60 accommodates the laser light source 20 and the mirror member 30.

In the example illustrated in FIG. 1B, the light-emitting device 100 includes a single laser light source 20 but may include a plurality of laser light sources 20. When the light-emitting device 100 includes a plurality of laser light sources 20, the number of the mirror members 30 may be equal to, or may be smaller than, the number of the laser light sources 20. When the number of the mirror members 30 is equal to the number of the laser light sources 20, each of the mirror members 30 corresponds to a respective one of the laser light sources 20. When the number of the mirror members 30 is smaller than the number of the laser light sources 20, a single mirror member 30 corresponds to two or more laser light sources 20.

These drawings schematically show the X axis, the Y axis and the Z axis, which are orthogonal to one another, for reference. The direction of the arrow of the X axis will be referred to as the +X direction, and a direction opposite to the +X direction will be referred to as the −X direction. Where the +X directions are not distinguished from each other, the direction will be referred to simply as the X direction. These also apply to the Y direction and the Z direction. In the present specification, the +Y direction will be also denoted as “upward”, and the −Y direction as “downward” for ease of understanding. This is not intended to limit the orientation in which the light-emitting device is used, and the light-emitting device can be used in any appropriate orientation.

FIG. 1C is another exploded perspective view of the light-emitting device 100 illustrated in FIG. 1A. In FIG. 1C, the plurality of wires 41 illustrated in FIG. 1B are not shown. FIG. 1D is a perspective view of the frame body 40 included in the light-emitting device 100 illustrated in FIG. 1A as viewed from below. FIG. 1E is a top view of the configuration of the light-emitting device 100 illustrated in FIG. 1A, in which the cover 50 is not shown. FIG. 1F is a cross-sectional view parallel to a YZ plane of the light-emitting device 100 illustrated in FIG. 1A. The bold arrows illustrated in FIG. 1F represent the traveling direction of the laser light L emitted from the laser light source 20. FIG. 1G shows a modification of the configuration illustrated in FIG. 1F, in which the upper surface 12 of the substrate 10 is partially modified.

In the light-emitting device 100 of the present embodiment, as illustrated in FIG. 1C, the upper surface 12 of the substrate 10 has a recessed portion 13 that has a bottom surface 15. The laser light source 20 and the mirror member 30 are disposed on the bottom surface 15 of the recessed portion 13. When the traveling direction of the laser light emitted from the laser light source 20 is referred to as a front side of the laser light source 20, the mirror member 30 is located on the front side of the laser light source 20. As illustrated in FIG. 1F, the laser light L emitted from the laser light source 20 is reflected by the reflective surface 32 of the mirror member 30 so as to travel in a direction away from the upper surface 12 and then transmitted through the cover 50. In this manner, the light-emitting device 100 emits the laser light L from the cover 50. The light-emitting device 100 is, for example, disposed on a flat mounting surface. For example, the lower surface 14 of the substrate 10 is disposed on a flat mounting surface.

Disadvantages of a configuration in which the upper surface 12 of the substrate 10 does not have the recessed portion 13, in contrast to the light-emitting device 100 of the present embodiment, will be described below. When a substrate having no recessed portion in the upper surface is bonded to the frame body 40 via an inorganic bonding material such as brazing material, heat is applied to the inorganic bonding material. If the thermal expansion coefficient of the substrate is higher than the thermal expansion coefficient of the frame body 40, the heat applied to the inorganic bonding material causes the substrate to deform relative to the frame body 40 and, as a result, the substrate tends to warp convexly upward. For example, if the substrate 10 is made of a metal material and the frame body 40 is made of a ceramic material whose thermal expansion coefficient is lower than that of the substrate 10, warpage in the substrate may occur. In this specification, a structure in which a substrate with no recessed portion in the upper surface and the frame body 40 are bonded together is also referred to as “base part main body”.

As illustrated in FIG. 1C, the substrate has a rectangular shape in a top view, as viewed from a position further in the +Y direction. The rectangular shape has long sides and short sides. When the substrate has a rectangular shape that has long sides and short sides, the above-described warpage in the substrate is greater in the long side direction (longitudinal direction) than in the short side direction (transverse direction). The semiconductor laser element 22 also has a rectangular shape, as does the substrate. From the viewpoint of reducing the size of the light-emitting device 100, the laser light source 20 is disposed on the upper surface of the substrate such that the long sides of the substrate and the long sides of the semiconductor laser element 22 are parallel to one another, in order to avoid wasting space. In such a case, due to large warpage in the substrate in the long side direction (longitudinal direction), the lower surface of the laser light source 20 fail to be sufficiently in contact with the upper surface of the substrate, and there is a probability that the heat radiated from the semiconductor laser element 22 during operation will not be effectively transferred to the substrate.

In contrast, in the light-emitting device 100 of the present embodiment, when the substrate 10 is made of, for example, a metal material, the substrate 10 has plasticity and, therefore, the recessed portion 13 can be formed in the upper surface 12 of the substrate 10 using a press machine. The press machine can include a stage that has a flat supporting surface and a pressing portion that has a flat-surface lower end. The lower end of the pressing portion can be adjusted so as to be parallel to the supporting surface of the stage. On the stage of the press machine, the above-described base part main body is placed such that the lower surface 14 of the substrate faces downward. Then, the upper surface of the substrate is pressed down by the pressing portion, whereby a recessed portion is formed in the upper surface of the substrate. In this manner, the substrate 10 that has the recessed portion 13 in the upper surface 12 is produced. By pressing, as compared with the upper surface of the substrate in which the recessed portion 13 is not yet formed, warpage in the bottom surface 15 of the recessed portion 13 is reduced and, more specifically, the bottom surface 15 results in a flat surface.

In the light-emitting device 100 of the present embodiment, the laser light source 20 is disposed on the flat bottom surface 15 and, therefore, the lower surface of the laser light source 20 is in uniform contact with the bottom surface 15. As a result, the heat radiated from the semiconductor laser element 22 during operation can be effectively transferred to the substrate 10. This facilitates improvement in the heat radiation from the light-emitting device 100.

Hereinafter, the components of the light-emitting device 100 are described.

### Substrate 10

As illustrated in FIG. 1C, the substrate 10 has an upper surface 12. The upper surface 12 has a recessed portion 13 that has a bottom surface 15. The substrate 10 further has a lower surface 14 located opposite to the upper surface 12. The bottom surface 15 is parallel to the XZ plane. The bottom surface 15 includes a flat region across its entirety. The lower surface 14 is also parallel to the XZ plane, as is the bottom surface 15. The lower surface 14 includes a flat region across its entirety. The bottom surface 15 and the lower surface 14 are parallel to each other. A direction normal to the bottom surface 15 is the +Y direction. In this specification, the direction normal to a surface means a direction perpendicular to the surface and away from an object having the surface. The effects exhibited by a structure in which the bottom surface 15 is flat, the lower surface 14 is flat, and the bottom surface 15 and the lower surface 14 are parallel to each other will be described later.

With respect to the lower surface 14 of the substrate 10, the distance in the Y direction from the highest part of the upper surface 12 of the substrate 10 to the lowest part of the bottom surface 15 is referred to as the depth of the recessed portion 13, the depth of the recessed portion 13 can be, for example, equal to or greater than 5 μm and equal to or smaller than 30 μm. The flatness of the flat region across the entire bottom surface 15 is, for example, equal to or smaller than 10 μm, and the flatness of the lower surface 14 is, for example, equal to or smaller than 20 μm.

According to JIS B 0621 “Definitions and Designations of Geometrical Deviations”, the flatness is defined as “the amount of deviation of a plane feature from the geometrically exact plane (geometrical plane)”. Specifically, the flatness corresponds to the distance between two exactly-flat planes that vertically sandwich an object plane.

The substrate 10 has a substantially flat plate shape. The substrate 10 has a rectangular shape in a top view. The substrate 10 has long sides and short sides. The recessed portion 13 has a rectangular shape in a top view. The recessed portion 13 has long sides and short sides. Preferably, the recessed portion 13 has a rectangular shape with rounded corners in a top view. With the rounded corners, concentration of stress around the corners can be inhibited even when the volume of the substrate 10 changes due to the heat radiated from the semiconductor laser element 22 during operation, as compared with a case where the corners are not rounded.

The thermal conductivity of the substrate 10 can be, for example, equal to or higher than 50 W/m·K and equal to or lower than 500 W/m·K. With the substrate 10 having such a thermal conductivity, the heat radiated from the semiconductor laser element 22 during operation can be effectively transferred to the mounting surface via the substrate 10.

The thermal expansion coefficient of the substrate 10 can be, for example, equal to or higher than 10×10⁻⁶ [1/K] and equal to or lower than 20×10⁻⁶ [1/K]. When the thermal expansion coefficient of the substrate 10 is higher than the thermal expansion coefficient of the frame body 40 and the substrate is bonded to the frame body 40 via an inorganic bonding material such as brazing material, the substrate tends to warp convexly upward due to the heat applied to the inorganic bonding material as previously described. When the substrate has plasticity, forming a recessed portion in the upper surface of the substrate using a processing method such as pressing allows for reducing warpage of the substrate can be reduced, resulting in the substrate 10 illustrated in FIG. 1C. As compared with the upper surface in which the recessed portion is not yet formed, warpage in the bottom surface 15 of the recessed portion 13 is reduced; more specifically, the bottom surface 15 of the recessed portion 13 is a flat surface.

The substrate 10 can be made of, for example, at least one metal material selected from the group consisting of Cu, Al and Ag. These metal materials have the thermal conductivity and the thermal expansion coefficient within the ranges described above, and has plasticity. The dimension in the X direction of the substrate 10 can be, for example, equal to or greater than 1 mm and equal to or smaller than 10 mm. The dimension in the Y direction of the substrate 10 can be, for example, equal to or greater than 0.1 mm and equal to or smaller than 5 mm. The dimension in the Z direction of the substrate 10 can be, for example, equal to or greater than 1 mm and equal to or smaller than 20 mm.

### Laser Light Source 20

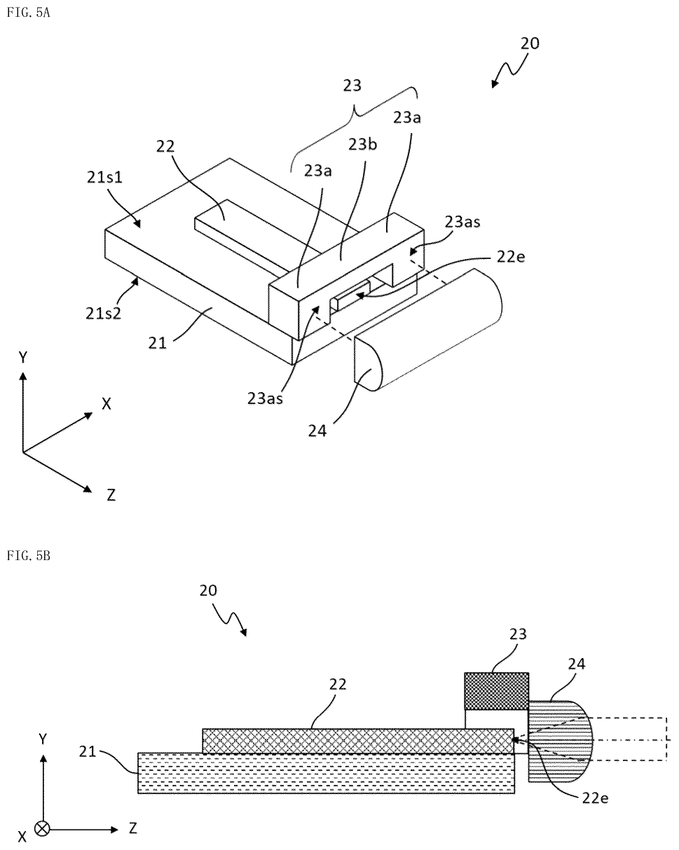

As illustrated in FIG. 1C, the laser light source 20 is disposed on the bottom surface 15 of the recessed portion 13 of the substrate 10. As illustrated in FIG. 5A and FIG. 5B, the laser light source 20 includes a submount 21, an edge-emitting semiconductor laser element 22, a lens support member 23, and a fast-axis collimating lens 24. The components of the laser light source 20 may be considered as the components of the light-emitting device 100. FIG. 5A is an exploded perspective view of the laser light source 20. FIG. 5B is a cross-sectional view parallel to the YZ plane of the laser light source 20. Hereinafter, the components of the laser light source 20 are described.

### Submount 21

As illustrated in FIG. 5A, the submount 21 has an upper surface 21s1 and a lower surface 21s2, which are parallel to the XZ plane. A metal film is disposed at each of the upper surface 21s1 and the lower surface 21s2. The metal film disposed at the upper surface 21s1 improves the bonding strength in bonding the semiconductor laser element 22 and the lens support member 23 to the submount 21 via a bonding material. The metal film disposed at the upper surface 21s1 may be further used to supply electric power to the semiconductor laser element 22. The metal film disposed at the lower surface 21s2 improves the bonding strength in bonding together the substrate 10 and the laser light source 20 illustrated in FIG. 1C via a bonding material. The metal films disposed at respective ones of the upper surface 21s1 and the lower surface 21s2 also facilitates transferring the heat radiated from the semiconductor laser element 22 during operation to the substrate 10 via the submount 21.

The submount 21 can also be made of, for example, the above-described ceramic material, as is the frame body 40 illustrated in FIG. 1C. The submount 21 can also be made of, for example, the above-described metal material, as is the substrate 10 illustrated in FIG. 1C. The submount 21 can be partially or entirely made of, for example, at least one selected from the group consisting of AlN, SiC, alumina, CuW, Cu, a multilayer structure of Cu/AlN/Cu, and a Metal Matrix Compound (MMC). The MMC contains, for example, diamond and at least one selected from the group consisting of Cu, Ag and Al. Alternatively, the submount 21 may be partially or entirely made of any common material.

The thermal conductivity of the submount 21 can be, for example, equal to or higher than 10 [W/m·K] and equal to or lower than 800 [W/m·K]. With the submount 21 having such a thermal conductivity, the heat radiated from the semiconductor laser element 22 during operation can be effectively transferred to the substrate 10. The thermal expansion coefficient of the submount 21 can be, for example, equal to or higher than 2×10⁻⁶ [1/K] and equal to or lower than 2×10⁻⁵ [1/K]. With the submount 21 having such a thermal expansion coefficient, in bonding the semiconductor laser element 22 to the submount 21 via a bonding material, the probability of deformation of the submount 21 due to the heat applied to the bonding material can be reduced.

The submount 21 is disposed on the bottom surface 15 of the recessed portion 13. As illustrated in FIG. 1E, in a top view, the outer boundary of the recessed portion 13 is located inward of the frame body 40. With this structure, when the submount 21 and the substrate 10 are bonded together using a bonding material, the molten bonding material is less likely to flow to the frame body 40 in the process of melting the bonding material by heating and then solidifying it by cooling. The bonding material can be, for example, at least one solder material selected from the group consisting of AuSn, SnCu, SnAg, and SnAgCu.

When the recessed portion 13 is formed by pressing, an elevated portion 16 can be generated around the recessed portion 13 as illustrated in FIG. 1G. Even if the elevated portion 16 is generated, it will not adversely affect the bonding strength between the substrate 10 and the frame body 40. Furthermore, the elevated portion 16 allows for reducing the probability that the molten bonding material will flow to the frame body 40.

The submount 21 and the substrate 10 can be bonded together with a sintering material. In sintering, particles or powder of a metal are heated at a temperature lower than the melting point of the metal and compacted, whereby the members are bonded together. The sintering material can be, for example, a metal paste. The metal paste includes an organic binder and a plurality of metal particles dispersed in the binder. The plurality of metal particles include, for example, at least one type of metal particles selected from the group consisting of Ag particles, Cu particles, Au particles, and other precious metal particles. Because the metal paste has flexibility, the position of the submount 21 can be finely adjusted when the submount 21 and the substrate 10 are bonded together by sintering the plurality of metal particles in the metal paste by heating.

### Semiconductor Laser Element 22

The semiconductor laser element 22 is supported by the upper surface 21s1 of the submount 21 as illustrated in FIG. 5A. That is, the semiconductor laser element 22 is disposed on the bottom surface 15 of the recessed portion 13 with the submount 21 disposed therebetween.

The semiconductor laser element 22 has a rectangular shape in a top view. The rectangular shape has long sides and short sides. The length of the long sides of the semiconductor laser element 22 can be, for example, equal to or greater than 1000 μm and equal to or smaller than 10000 μm. The semiconductor laser element 22 is configured to emit a high-power laser light of, for example, 10 W or more. The semiconductor laser element 22 produces a large amount of heat during operation. The amount of the produced heat increases as the semiconductor laser element 22 becomes longer. As illustrated in FIG. 1C, from the viewpoint of reducing the size of the light-emitting device 100, the laser light source 20 is disposed on the bottom surface 15 of the recessed portion 13 such that the long sides of the substrate 10 and the long sides of the semiconductor laser element 22 are parallel to one another, in order to avoid wasting space. In such a case, with the bottom surface 15 being a flat surface, the lower surface of the submount 21 is in uniform contact with the bottom surface 15, so that the heat radiated from the elongated semiconductor laser element 22 during operation can be effectively transferred to the substrate 10 via the submount 21. This facilitates improvement in the heat radiation from the light-emitting device 100.

The semiconductor laser element 22 is arranged to emit the laser light L toward the reflective surface 32 of the mirror member 30. When the emission surface of the semiconductor laser element 22 is parallel to an XY plane where the X direction is the longitudinal direction, the laser light L emitted in the +Z direction from the semiconductor laser element 22 diverges relatively fast in the YZ plane but relatively slow in the XZ plane. The fast axis direction of the laser light L is parallel to the Y direction, and the slow axis direction of the laser light L is parallel to the X direction.

The bottom of the semiconductor laser element 22 is located at a position raised by the submount 21, the laser light L, which diverges while traveling, is allowed to be entirely incident on the reflective surface 32 of the mirror member 30. The laser light L, which diverges while traveling, is reflected by the reflective surface 32 and then transmitted through the cover 50.

The distance in the Y direction from the upper surface 12 of the substrate 10 to the bottom surface 15 of the recessed portion 13 is shorter than the distance in the Y direction from the upper surface of the semiconductor laser element 22 to the bottom surface 15 of the recessed portion 13. The distance in the Y direction from the upper surface 12 of the substrate 10 to the bottom surface 15 of the recessed portion 13 is shorter than the distance in the Y direction from the upper surface of the semiconductor laser element 22 to the lower surface of the semiconductor laser element 22. Due to such a relationship in distance, even when the recessed portion 13 is formed in the upper surface 12 of the substrate 10, it is not necessary to greatly change the size of the substrate 10 for formation of the recessed portion 13. That is, the heat radiation from the light-emitting device 100 can be improved by forming the recessed portion 13 without increasing the size of the light-emitting device 100.

Herein, the distance in the Y direction from the upper surface 12 of the substrate 10 to the bottom surface 15 of the recessed portion 13 refers to the distance in the Y direction from the highest part of the upper surface 12 of the substrate 11 to the lowest part of the bottom surface 15 of the recessed portion 13. The distance in the Y direction from the upper surface of the semiconductor laser element 22 to the bottom surface 15 of the recessed portion 13 means the distance in the Y direction from the upper surface of the semiconductor laser element 22 to the lowest part of the bottom surface 15 of the recessed portion 13.

The semiconductor laser element 22 has an emission surface 22e at one of the two end surfaces, which intersect the Z direction, and is configured to emit a laser light in the +Z direction from the emission surface 22e. While traveling in the +Z direction, the laser light diverges at different speeds in the YZ plane and the XZ plane. The laser light diverges relatively fast in the YZ plane but relatively slow in the XZ plane. The spot of the laser light, when not collimated, has an elliptical shape in the far field, with the major axis in the Y direction and the minor axis in the X direction in the XY plane.

A part of the laser light whose intensity is equal to or greater than 1/e² of the peak intensity in any plane perpendicular to the traveling direction of the laser light is considered as the major part. e is the base of the natural logarithm. In this specification, the divergence of the laser light means the divergence of the major part of the laser light.

The semiconductor laser element 22 can emit a violet, blue, green or red laser light in the visible light range or an infrared or ultraviolet laser light in the invisible light range. The emission peak wavelength of the violet laser light is preferably equal to or greater than 400 nm and equal to or less than 420 nm, more preferably equal to or greater than 400 nm and equal to or less than 415 nm. The emission peak wavelength of the blue laser light is preferably greater than 420 nm and equal to or less than 495 nm, more preferably equal to or greater than 440 nm and equal to or less than 475 nm. The emission peak wavelength of the green laser light is preferably greater than 495 nm and equal to or less than 570 nm, more preferably equal to or greater than 510 nm and equal to or less than 550 nm. The emission peak wavelength of the red laser light is preferably equal to or greater than 605 nm and equal to or less than 750 nm, more preferably equal to or greater than 610 nm and equal to or less than 700 nm.

Examples of the semiconductor laser element 22 that emits the violet light, blue light, and the green light include a laser diode including a nitride semiconductor material. For example, GaN, InGaN, and AlGaN can be used as the nitride semiconductor material. Examples of the semiconductor laser element 22 that emits the red light include a laser diode including an InAlGaP-based, a GaInP-based, a GaAs-based, and a AlGaAs-based semiconductor material.

Instead of the edge-emitting semiconductor laser element 22, a surface-emitting semiconductor laser element, such as a vertical-cavity surface-emitting laser (VCSEL) element, may also be used. The surface-emitting semiconductor laser element is arranged such that the laser light emitted from the semiconductor laser element travels in the +Z direction. Alternatively, a surface-emitting semiconductor laser element may be arranged such that a laser light emitted from the semiconductor laser element travels in the +Y direction. In such a case, it is not necessary to provide the mirror member 30, which will be described later.

### Lens Support Member 23

As illustrated in FIG. 5A, the lens support member 23 is supported by the upper surface 21s1 of the submount 21. The lens support member 23 may be disposed on the submount 21 to be supported by the front surface or side surface of the submount 21. The lens support member 23 includes two columnar portions 23a and a connecting portion 23b that is positioned between the two columnar portions 23a and connects the two columnar portions 23a. The two columnar portions 23a are positioned on two opposite sides of the semiconductor laser element 22, and the connecting portion 23b is positioned above the semiconductor laser element 22 at the emission surface 22e side. The lens support member 23 supports the fast-axis collimating lens 24 at end surfaces 23 as of the two columnar portions 23a. The lens support member 23 is arranged straddling the semiconductor laser element 22 and does not obstruct the laser light emitted from the semiconductor laser element 22 from being incident on the fast-axis collimating lens 24.

The lens support member 23 can also be made of, for example, the above-described ceramic material, as is the frame body 40 illustrated in FIG. 1C. The lens support member 23 can also be made of, for example, the above-described light-transmissive material, as is the cover 50 illustrated in FIG. 1C. The lens support member 23 can be made of, for example, at least one alloy selected from the group consisting of Kovar and CuW. The lens support member 23 can be made of, for example, Si.

With the semiconductor laser element 22 and the lens support member 23 disposed on the submount 21, the relative positional relationship between the semiconductor laser element 22 and the fast-axis collimating lens 24 is fixed irrespective of where the laser light source 20 is positioned. Therefore, a deviation would not occur in the positional relationship.

### Fast-Axis Collimating Lens 24

The fast-axis collimating lens 24 can be, for example, a cylindrical lens having a cross-sectional shape which is uniform in the X direction as illustrated in FIG. 5A. The fast-axis collimating lens 24 has a flat surface on the light entry side and a convex curved surface on the light exit side. The convex curved surface has a curvature in the YZ plane. The focal point of the fast-axis collimating lens 24 substantially coincides with the center of a light emission point in the emission surface 22e of the semiconductor laser element 22. As illustrated in FIG. 5B, the fast-axis collimating lens 24 collimates the laser light emitted in the +Z direction from the emission surface 22e of the semiconductor laser element 22 such that the laser light is collimated in the fast axis direction in the YZ plane. In this specification, “collimating” means not only making the laser light L parallel light but also reducing the divergence angle of the laser light L. A region surrounded by a broken line in FIG. 5B represents a region in which the intensity of the laser light is equal to or greater than 1/e² times the peak intensity of the laser light. The fast-axis collimating lens 24 can be made of, for example, at least one light-transmitting material selected from the group consisting of glass, silicon, quartz, synthetic quartz, sapphire, and transparent ceramic materials.

As illustrated in FIG. 1F, the fast-axis collimating lens 24 is positioned between the upper surface 12 of the substrate 10 and the lower surface 54 of the cover 50 and is positioned on the optical path of the laser light L. With the fast-axis collimating lens 24 located inside the sealed space formed by the substrate 10, the frame body 40 and the cover 50, the fast-axis collimating lens 24 can collimate the laser light L before the laser light L largely diverges. Therefore, the fast-axis collimating lens 24 can have a small size.

Instead of the fast-axis collimating lens 24, a collimating lens configured to collimate the laser light L emitted from the semiconductor laser element 22 not only in the YZ plane but also in the XZ plane may be used. Alternatively, instead of the fast-axis collimating lens 24, a condenser lens configured to converge the laser light L emitted from the semiconductor laser element 22 may be used.

With the foregoing settings, the laser light source 20 disposed on the flat bottom surface 15 emits the laser light L in the +Z direction that is parallel to the bottom surface 15 as illustrated in FIG. 1F. The phrase “emit a laser light L in the +Z direction” encompasses a case in which the traveling direction of the laser light L emitted from the laser light source 20 is not strictly parallel to the +Z direction so long as the absolute value of the angle between the traveling direction of the laser light L emitted from the laser light source 20 and the +Z direction is equal to or smaller than 0.5°. The laser light L emitted from the laser light source 20 is collimated in the YZ plane but not collimated in the XZ plane. The semiconductor laser element 22 included in the laser light source 20 is sealed by the substrate 10, the frame body 40 and the cover 50 as illustrated in FIG. 1F. This seal is preferably a hermetic seal. The effect of the hermetic seal increases as the wavelength of the laser light L emitted from the semiconductor laser element 22 becomes shorter. This is because, in a configuration where the semiconductor laser element 22 is not hermetically sealed and the emission surface of the semiconductor laser element 22 is exposed the outside air, as the wavelength of the laser light L is shorter, the emission surface is more likely to gradually deteriorate due to dust attraction while the semiconductor laser element 22 is in operation. That is, when the semiconductor laser element 22 is hermetically sealed, the emission surface of the semiconductor laser element 22 can be protected from attracted dust. As illustrated in FIG. 1C, from the viewpoint of reducing the size of the light-emitting device 100, the laser light source 20 is disposed on the bottom surface 15 of the recessed portion 13 such that the long sides of the substrate 10 and the long sides of the semiconductor laser element 22 are parallel to one another, in order to avoid wasting space. Reduction in the size of the light-emitting device 100 can facilitate the hermetic sealing.

### Mirror Member 30

The mirror member 30 is disposed on the bottom surface 15 of the recessed portion 13 of the substrate 10 as illustrated in FIG. 1C. The mirror member 30 and the laser light source 20 are arranged side-by-side along the long side direction (longitudinal direction) of the substrate 10. The mirror member 30 has a cross-sectional shape which is uniform in the X direction. The cross-sectional shape is substantially triangular. The mirror member 30 has a lower surface, a back surface, and an inclined surface connecting the lower surface and the back surface. The lower surface is parallel to the XZ plane and the back surface is parallel to the XY plane. The normal direction of the inclined surface is a direction which is parallel to the YZ plane, which forms an acute angle with the +Y direction, and which forms an acute angle with the −Z direction. The angle formed between the lower surface and the inclined surface of the mirror member 30 is 45° in the example herein, but is not limited thereto.

For example, this angle may be in a range from 30° to 60°.

The mirror member 30 has a flat reflective surface 32. The reflective surface 32 is inclined with respect to the upper surface 12 of the substrate 10 and faces obliquely upward. In this specification, “obliquely upward” means a direction forming an angle in a range from 30° to 60° with the +Y direction. The normal direction of the reflective surface 32 may be or may not be parallel to the YZ plane as long as the reflective surface 32 can receive the laser light L emitted from the laser light source 20 and the normal direction of the reflective surface 32 forms an angle in the range from 30° to 60° with the +Y direction.

As illustrated in FIG. 1F, the reflective surface 32 of the mirror member 30 disposed on the flat bottom surface 15 reflects the laser light L emitted from the laser light source 20 to change the traveling direction of the laser light L into a direction away from the upper surface 12 of the substrate 10. In the example illustrated in FIG. 1F, the direction away from the upper surface 12 of the substrate 10 is the +Y direction that is perpendicular to the bottom surface 15 of the recessed portion 13. The phrase “traveling in the +Y direction” encompasses a case in which the traveling direction of the laser light L reflected by the reflective surface 32 is not strictly parallel to the +Y direction so long as the absolute value of the angle between the traveling direction of the laser light L reflected by the reflective surface 32 and the +Y direction is equal to or smaller than 0.5°.

Unlike the light-emitting device 100 of the present embodiment, when the base part 60 in the example illustrated in FIG. 1F is replaced by the above-described base part main body, the upper surface of the substrate of the base part main body does not have the recessed portion 13 and, therefore, the substrate warpage is not reduced. When the laser light source 20 and the mirror member 30 are disposed on the upper surface of the substrate that is warped convexly upward, the relative positional relationship between the laser light source 20 and the mirror member 30 deviates. This causes the traveling direction of the laser light L emitted from the laser light source 20 to deviate from the +Z direction, so that the traveling direction of the laser light L having been emitted from the laser light source 20 and reflected by the reflective surface 32 of the mirror member 30 can deviate from the +Y direction. Thus, the traveling direction of the laser light L emitted from the light-emitting device deviates from the designed traveling direction, i.e., the +Y direction.

In contrast, in the light-emitting device 100 of the present embodiment, the laser light source 20 and the mirror member 30 are disposed on the flat bottom surface 15 of the recessed portion 13, so that the deviation of the relative positional relationship between the laser light source 20 and the mirror member 30 can be reduced. Therefore, the deviation of the traveling direction of the laser light L emitted from the laser light source 20 from the +Z direction is reduced, and the deviation of the traveling direction of the laser light L emitted from the laser light source 20 and reflected by the reflective surface 32 of the mirror member 30 from the +Y direction is also reduced. Accordingly, the deviation of the traveling direction of the laser light L emitted from the light-emitting device 100 from the designed traveling direction, i.e., the +Y direction, can be reduced. The designed traveling direction is not limited to the +Y direction but may be any appropriate direction.

The mirror member 30 includes, for example, a base having an inclined surface and a reflective surface provided at the inclined surface. The base can be made of, for example, at least one material selected from the group consisting of glass, quartz, synthetic quartz, sapphire, ceramic material, silicone, metal, and dielectric material. The reflective surface may be made of, for example, a reflective material, such as a dielectric multilayer film and a metal material. This reflective surface corresponds to the reflective surface 32.

Alternatively, the mirror member 30 may include, for example, a base having an inclined surface, and the base may be made of the above-described reflective material. In this case, the inclined surface of the base corresponds to the reflective surface 32.

### Frame Body 40

The frame body 40 is positioned around the upper surface 12 of the substrate 10, as illustrated in FIG. 1B, and supports the cover 50 as illustrated in FIG. 1A. As illustrated in FIG. 1B, in a top view, the frame body 40 surrounds the laser light source 20 and the mirror member 30. As illustrated in FIG. 1C, the frame body 40 includes a protruding portion 43 protruding inward from the inner surface. In the example illustrated in FIG. 1E, the protruding portion 43 protrudes toward two opposite lateral surfaces and the back surface of the submount 21. Further, the protruding portion 43 may protrude toward the front surface of the submount 21. Alternatively, the protruding portion 43 may protrude only toward the two opposite lateral surfaces. The front surface of the submount 21 is positioned on the same side as the emission surface of the semiconductor laser element 22, and the back surface of the submount 21 is positioned on the side opposite to the emission surface of the semiconductor laser element 22. The two opposite lateral surfaces of the submount 21 connect the front surface and the back surface of the submount 21.

The frame body 40 has a first upper surface 42a and a second upper surface 42b as illustrated in FIG. 1C. The second upper surface 42b is the upper surface of the protruding portion 43. The second upper surface 42b is positioned lower than the first upper surface 42a and surrounded by the first upper surface 42a in a top view. In the example illustrated in FIG. 1E, the second upper surface 42b has a substantially U-shape.

The first upper surface 42a includes a first bonding region 46a and an outer region 47 surrounding the first bonding region 46a. The first bonding region 46a and the outer region 47 have a substantially rectangular annular shape. The first bonding region 46a improves the bonding strength in bonding together the cover 50 and the frame body 40 via a bonding material such as a solder material. The outer region 47 reduces the probability that the bonding material for bonding the cover 50 will flow out beyond the outer region 47. As illustrated in FIG. 1E, in a top view, the first bonding region 46a and the outer region 47 surround the laser light source 20 and the mirror member 30. The first upper surface 42a further includes a first electrically-conductive region 48a and a second electrically-conductive region 48b, which are electrically insulated from each other, on the −Z direction side relative to the first bonding region 46a and the outer region 47.

The second upper surface 42b includes a third electrically-conductive region 48c and a fourth electrically-conductive region 48d, which are electrically insulated from each other. The third electrically-conductive region 48c is electrically connected with the first electrically-conductive region 48a via internal wiring. The fourth electrically-conductive region 48d is electrically connected with the second electrically-conductive region 48b via internal wiring. As illustrated in FIG. 1E, in a top view, the laser light source 20 and the mirror member 30 are positioned between a portion of the third electrically-conductive region 48c extending in the Z direction and a portion of the fourth electrically-conductive region 48d extending in the Z direction. The third electrically-conductive region 48c is electrically coupled with the semiconductor laser element 22 via the upper surface of the submount 21 and some of the wires 41. The fourth electrically-conductive region 48d is electrically coupled with the semiconductor laser element 22 via the remaining wires 41. Therefore, by applying a voltage between the first electrically-conductive region 48a and the second electrically-conductive region 48b, electric power can be supplied to the laser light source 20.

As illustrated in FIG. 1D, the frame body 40 further includes a first lower surface 44a and a second lower surface 44b. The second lower surface 44b partially includes the lower surface of the protruding portion 43. The second lower surface 44b is positioned higher than the first lower surface 44a and is surrounded by the first lower surface 44a as viewed from the −Y direction, i.e., in a bottom view. The second lower surface 44b has a substantially rectangular annular shape. A part or an entirety of the substrate 10 illustrated in FIG. 1C is accommodated in a space surrounded by the step between the first lower surface 44a and the second lower surface 44b. When the frame body 40 is viewed transparently, the outer periphery of the second lower surface 44b surrounds the outer periphery of the upper surface 12 of the substrate 10 in a top view, and the inner periphery of the second lower surface 44b is surrounded by the outer periphery of the upper surface 12 of the substrate 10 in a top view.

The inner lateral surface of the frame body 40 defines an opening 45 extending from the first upper surface 42a to the first lower surface 44a as illustrated in FIG. 1D. The opening 45 is partially defined by the second lower surface 44b, which corresponds to a stepped portion, in the inner lateral surface at the lower surface side. A second bonding region 46b is provided over the entire second lower surface 44b. The peripheral region of the upper surface 12 of the substrate 10 is bonded to the second bonding region 46b provided at the stepped portion via an inorganic bonding material such as brazing material. Examples of the brazing material include silver brazing material. The second bonding region 46b allows for improving the bonding strength in bonding together the substrate 10 and the frame body 40 via an inorganic bonding material. The melting point of the brazing material is higher than the melting point of the solder material. Therefore, when the brazing material is heated to bond together the substrate 10 and the frame body 40 and thereafter the solder material is heated to bond together the substrate 10 and the laser light source 20, the heat applied to the solder material is less likely to break the bond between the substrate 10 and the frame body 40. As the inorganic bonding material, for example, AuSn, Au paste, and Ag paste may be used.

In the example illustrated in FIG. 1D, the second bonding region 46b is provided over the entire second lower surface 44b, but is not limited thereto. The second bonding region 46b may be provided over a part of the second lower surface 44b.

The first lower surface 44a of the frame body 40 is at a position higher than the lower surface 14 of the substrate 10 as illustrated in FIG. 1F. In other words, the distance in the Y direction from the upper surface 12 of the substrate 10 to the lower surface 14 of the substrate 10 is longer than the distance in the Y direction from the upper surface 12 of the substrate 10 to the first lower surface 44a of the frame body 40. Herein, the distance in the Y direction from the upper surface 12 of the substrate 10 to the lower surface 14 of the substrate 10 refers to the distance in the Y direction from the highest part of the upper surface 12 of the substrate 10 to the lowest part of the lower surface 14 of the substrate 10. The distance in the Y direction from the upper surface 12 of the substrate 10 to the first lower surface 44a of the frame body 40 refers to the distance in the Y direction from the highest part of the upper surface 12 of the substrate 10 to the lowest part of the first lower surface 44a of the frame body 40.

When the light-emitting device 100 is disposed on a flat mounting surface, the lower surface 14 of the substrate 10 is supported by the mounting surface. The lower surface 14 of the substrate 10 is bonded to the mounting surface via, for example, a bonding material such as solder material. When the lower surface 14 of the substrate 10 is flat, the entirety of the lower surface 14 is in uniform contact with the mounting surface via the bonding material and, therefore, the heat radiated from the semiconductor laser element 22 during operation can be effectively transferred to the mounting surface via the substrate 10. This facilitates improvement in the heat radiation from the light-emitting device 100. With the entirety of the lower surface 14 being in uniform contact with the mounting surface via the bonding material, the light-emitting device 100 can be stably disposed. Further, when the light-emitting device 100 is arranged on the flat mounting surface, the bottom surface 15 of the recessed portion 13 is parallel to the lower surface 14 of the substrate 10 and, therefore, the deviation of the traveling direction of the laser light L outgoing from the light-emitting device 100 from the designed traveling direction, i.e., the +Y direction, can be effectively reduced.

Note that the first lower surface 44a of the frame body 40 may be coplanar with the lower surface 14 of the substrate 10. In other words, the distance in the Y direction from the upper surface 12 of the substrate 10 to the lower surface 14 of the substrate 10 may be equal to the distance in the Y direction from the upper surface 12 of the substrate 10 to the first lower surface 44a of the frame body 40. Alternatively, the first lower surface 44a of the frame body 40 may be at a position lower than the lower surface 14 of the substrate 10 so long as this positioning does not obstruct the bonding of the substrate 10 to the mounting surface via the inorganic bonding material. In other words, the distance in the Y direction from the upper surface 12 of the substrate 10 to the lower surface 14 of the substrate 10 may be shorter than the distance in the Y direction from the upper surface 12 of the substrate 10 to the first lower surface 44a of the frame body 40. When the first lower surface 44a of the frame body 40 is at a position lower than the lower surface 14 of the substrate 10, it is preferred that only the lower surface 14 of the substrate 10 is in contact with the mounting surface. In a top view, the mounting surface overlaps the lower surface 14 of the substrate 10 but does not overlap the first lower surface 44a of the frame body 40.

With the configuration in which the lower surface 14 of the substrate 10 is in contact with the mounting surface even when the first lower surface 44a of the frame body 40 is at a position lower than the lower surface 14 of the substrate 10, the heat radiated from the semiconductor laser element 22 during operation can be effectively transferred to the mounting surface via the substrate 10. This facilitates improvement in the heat radiation from the light-emitting device 100. Further, with the configuration in which only the lower surface 14 of the substrate 10 is in contact with the mounting surface even when the first lower surface 44a of the frame body 40 is at a position lower than the lower surface 14 of the substrate 10, the bottom surface 15 of the recessed portion 13 is parallel to the mounting surface. Thus, the effect of reducing the deviation of the traveling direction of the laser light L by pressing of the substrate 10 can be sufficiently exhibited.

The frame body 40 can be made of, for example, a ceramic material selected from the group consisting of AlN, SiN, SiC, and alumina. The thermal expansion coefficient of the frame body 40 can be, for example, equal to or higher than 2×10⁻⁶ [1/K] and equal to or lower than 15×10⁻⁶ [1/K]. The dimension in the X direction of the frame body 40 can be, for example, equal to or greater than 3 mm and equal to or smaller than 30 mm. The maximum dimension in the Y direction of the frame body 40 can be, for example, equal to or greater than 1 mm and equal to or smaller than 5 mm. The dimension in the Z direction of the frame body 40 can be, for example, equal to or greater than 3 mm and equal to or smaller than 30 mm.

The first bonding region 46a, the second bonding region 46b, the outer region 47, and the electrically-conductive regions 48a, 48b, 48c, 48d can be made of, for example, at least one metal material selected from the group consisting of Ag, Cu, W, Au, Ni, Pt, and Pd. The first bonding region 46a, the outer region 47, and the electrically-conductive regions 48a, 48b, 48c, 48d can be formed by, for example, forming a metal film over the entirety of the first upper surface 42a and the second upper surface 42b and patterning the metal film by etching.

### Cover 50

The cover 50 is supported by the first upper surface 42a of the frame body 40 illustrated in FIG. 1C. The cover 50 has an upper surface 52 and a lower surface 54 as illustrated in FIG. 1B. The lower surface 54 of the cover 50 faces the upper surface 12 of the substrate 10, and the upper surface 52 of the cover 50 is located opposite to the lower surface 54 of the cover 50. Considering that the lower surface 54 of the cover 50 faces the upper surface 12 of the substrate 10, the lower surface 54 may also be referred to as “facing surface”. The cover 50 is located above the laser light source 20, more specifically above the semiconductor laser element 22. The cover 50 is also located above the mirror member 30.

The cover 50 is configured to transmit the laser light L reflected by the reflective surface 32. More specifically, the cover 50 includes a light transmitting portion 56 as illustrated in FIG. 1C, and the light transmitting portion 56 is configured to transmit the laser light L reflected by the reflective surface 32.

The cover 50 may include a light-shielding film 58 at a location exclusive of the light transmitting region through which the laser light L is to be transmitted. In the example illustrated in FIG. 1C, the cover 50 includes the light-shielding film 58 at least around the light transmitting region of the lower surface 54 through which the laser light L is to be transmitted. The light transmitting region corresponds to the lower surface of the light transmitting portion 56. In the example illustrated in FIG. 1C, the light transmitting region has a rectangular shape but is not limited to this shape. For example, the shape of the light transmitting region may be circular or may be elliptical. Note that the light-shielding film 58 may be provided at the upper surface 52 of the cover 50.

With the light-shielding film 58, a portion of the light produced inside the light-emitting device 100 exclusive of the laser light L, i.e., stray light, is less likely to leak out of the light-emitting device 100. Further, with the light-shielding film 58, return light of the laser light L emitted from the light-emitting device 100 is less likely to reach the laser light source 20. If irradiation with the return light is reduced, the laser light source 20 is less likely to be damaged.

In the example illustrated in FIG. 1C, the light-shielding film 58 is provided over the entire region of the lower surface 54 except for the lower surface of the light transmitting portion 56. Such an arrangement of the light-shielding film 58 allows for further reducing the probability that the above-described stray light will leak out of the light-emitting device 100 and the probability that the above-described return light will reach the laser light source 20.

The light transmitting portion 56 of the cover 50, which is configured to transmit the laser light L, can have a transmittance of 60% or higher, preferably 80% or higher, for the laser light L. The remaining portion of the cover 50 may have, or may not have, such a transmittance.

The cover 50 can be made of, for example, at least one light-transmitting material selected from the group consisting of glass, silicon, quartz, synthetic quartz, sapphire, and transparent ceramic materials. The dimension in the X direction of the cover 50 can be, for example, equal to or greater than 3 mm and equal to or smaller than 15 mm. The dimension in the Y direction of the cover 50 can be, for example, equal to or greater than 0.1 mm and equal to or smaller than 1.5 mm. The dimension in the Z direction of the cover 50 can be, for example, equal to or greater than 1 mm and equal to or smaller than 20 mm.

The light-shielding film 58 can also be made of, for example, the above-described metal material, as are the first bonding region 46a, the second bonding region 46b, the outer region 47, and the electrically-conductive regions 48a, 48b, 48c, 48d. The light-shielding film 58 can also be formed by, for example, forming a metal film over the entirety of the lower surface 54 of the cover 50 and patterning the metal film by etching, as are the first bonding region 46a, the second bonding region 46b, the outer region 47, and the electrically-conductive regions 48a, 48b, 48c, 48d.

The peripheral region of the light-shielding film 58 is bonded to the first bonding region 46a provided in the first upper surface 42a of the frame body 40 via a bonding material such as solder material. When the light-shielding film 58 is made of the above-described metal material, the light-shielding film 58 allows for improving the bonding strength in bonding together the cover 50 and the frame body 40 via the bonding material.

Note that the cover 50 has a flat plate shape in the example illustrated in FIG. 1A, FIG. 1B and FIG. 1C but is not limited to this shape. In the light-emitting device 100, the cover 50 may have a box shape with the open bottom. In the case of such a shape, the frame body 40 and the cover 50 are bonded together such that the lower surface of the cover 50 is supported by the first upper surface 42a of the frame body 40.

Thus, in the light-emitting device 100 of the present embodiment, from the viewpoint of reducing the size of the light-emitting device 100, the laser light source 20 is disposed on the bottom surface 15 of the recessed portion 13 such that the long sides of the semiconductor laser element 22 and the long sides of the substrate 10 are parallel to one another, in order to avoid wasting space. In such a case, the lower surface of the submount 21 is in uniform contact with the bottom surface 15 because the bottom surface 15 is flat and, therefore, the heat radiated from the elongated semiconductor laser element 22 during operation can be effectively transferred to the substrate 10 via the submount 21. This facilitates improvement in the heat radiation from the light-emitting device 100.

Furthermore, in the light-emitting device 100 of the present embodiment, when the light-emitting device 100 is disposed on the flat mounting surface, the entirety of the flat lower surface 14 of the substrate 10 is in uniform contact with the mounting surface via a bonding material and, therefore, the heat radiated from the semiconductor laser element 22 during operation can be effectively transferred to the mounting surface via the substrate 10. With the entirety of the flat lower surface 14 of the substrate 10 being in uniform contact with the mounting surface via a bonding material, the light-emitting device 100 can be stably disposed.

Furthermore, in the light-emitting device 100 of the present embodiment, the laser light source 20 and the mirror member 30 are disposed on the flat bottom surface 15 of the recessed portion 13, so that the deviation of the traveling direction of the laser light L emitted from the laser light source 20 from the +Z direction can be reduced, and the deviation of the traveling direction of the laser light L reflected by the reflective surface 32 from the +Y direction can be reduced. As a result, the deviation of the traveling direction of the laser light L outgoing from the light-emitting device 100 from the designed traveling direction, i.e., the +Y direction, can be reduced.

Furthermore, in the light-emitting device 100 of the present embodiment, when the light-emitting device 100 is disposed on a flat mounting surface, the bottom surface 15 of the recessed portion 13 and the lower surface 14 of the substrate 10 are parallel to each other, so that the deviation of the traveling direction of the laser light L outgoing from the light-emitting device 100 from the designed traveling direction, i.e., the +Y direction, can be effectively reduced.

The light-emitting device 100 of the present embodiment may further include an additional mirror member disposed on the upper surface 52 of the cover 50. The reflective surface of the additional mirror member is configured to reflect the laser light L, which has been reflected by the reflective surface 32 and then transmitted through the cover 50, so as to travel in a direction different from the +Y direction. The direction different from the +Y direction can be, for example, the +Z direction. The light-emitting device 100 of the present embodiment may further include a slow-axis collimating lens disposed on the upper surface 52 of the cover 50 illustrated in FIG. 1B. The slow-axis collimating lens is configured to collimate the laser light L, which has been reflected by the reflective surface 32 and then transmitted through the cover 50, in the slow axis direction in the XY plane. Alternatively, the light-emitting device 100 of the present embodiment may further include both an additional mirror member and a slow-axis collimating lens disposed on the upper surface 52 of the cover 50. The reflective surface of the additional mirror member is configured to reflect the laser light L, which has been reflected by the reflective surface 32 and then transmitted through the cover 50, so as to travel in a direction different from the +Y direction. The slow-axis collimating lens is configured to collimate the laser light L, which has been reflected by the reflective surface of the additional mirror member, in the slow axis direction.

### Variation Example of Light-Emitting Device 100

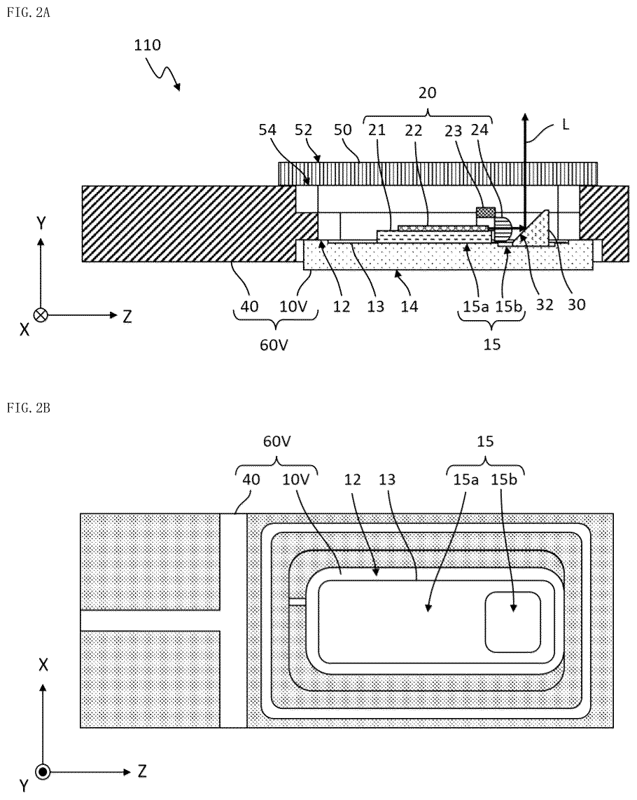

Next, a variation example of the light-emitting device 100 of the present embodiment is described with reference to FIG. 2A and FIG. 2B. FIG. 2A is a cross-sectional view parallel to the YZ plane, schematically illustrating the configuration of the variation example of the light-emitting device 100 of the present embodiment. The light-emitting device 110 illustrated in FIG. 2A is different from the light-emitting device 100 of the present embodiment in that the light-emitting device 110 includes a substrate 10V in place of the substrate 10. In this specification, a structure formed by bonding together the substrate 10V and the frame body 40 is also referred to as “base part 60V”. FIG. 2B is a top view of the configuration of the base part 60V for use in the light-emitting device 110 illustrated in FIG. 2A.

The substrate 10V has an upper surface 12 and a lower surface 14 as illustrated in FIG. 2A. The upper surface 12 has a recessed portion 13 that has a bottom surface 15. The bottom surface 15 of the recessed portion 13 includes the first bottom surface 15a on which the laser light source 20 is disposed and the second bottom surface 15b on which the mirror member 30 is disposed. The difference between the embodiment and the variation example resides in the presence/absence of the second bottom surface 15b of the recessed portion 13. The other components than the second bottom surface 15b are the same as those described above.

With respect to the lower surface 14 of the substrate 10, the second bottom surface 15b is at a position lower than the first bottom surface 15a (a distance between the lower surface 14 of the substrate 10 and the first bottom surface 15a is longer than a distance between the lower surface 14 of the substrate 10 and the second bottom surface 15b). Therefore, the bottom surface 15 has a stepped portion formed between the first bottom surface 15a and the second bottom surface 15b. The recessed portion 13, more specifically the outer edges of the first bottom surface 15a of the recessed portion 13, has a rectangular shape with rounded corners in a top view. The same applies to the outer edges of the second bottom surface 15b that is present inside the recessed portion 13. With the rounded corners of the recessed portion 13, concentration of stress around the corners of the recessed portion 13 can be reduced. The lower surface 14 of the substrate 10V is the same as the lower surface 14 of the substrate 10 illustrated in FIG. 1C.

When the distance in the Y direction from the highest part of the upper surface 12 to the lowest part of the first bottom surface 15a with respect to the lower surface 14 of the substrate 10V is referred to as the first depth of the recessed portion 13, the first depth of the recessed portion 13 can be, for example, equal to or greater than 5 μm and equal to or smaller than 30 μm. When the distance in the Y direction from the highest part of the upper surface 12 to the lowest part of the second bottom surface 15b with respect to the lower surface 14 of the substrate 10V is referred to as the second depth of the recessed portion 13, the second depth of the recessed portion 13 can be, for example, equal to or greater than 5 μm and equal to or smaller than 50 μm. The first bottom surface 15a and the second bottom surface 15b are flat and parallel to each other. Although the bottom surface 15 has a step between the first bottom surface 15a and the second bottom surface 15b, the bottom surface 15 includes flat regions in the first bottom surface 15a and the second bottom surface 15b. The lower surface 14 of the substrate 10V is also flat, as are the first bottom surface 15a and the second bottom surface 15b. The lower surface 14 of the substrate 10V includes a flat region across its entirety. The first bottom surface 15a and the second bottom surface 15b are parallel to the lower surface 14 of the substrate 10V. The flatness of the first bottom surface 15a and the second bottom surface 15b, which are flat regions in the bottom surface 15, is for example equal to or smaller than 10 μm, and the flatness of the lower surface 14 is for example equal to or smaller than 20 μm.

As illustrated in FIG. 2B, in a top view, the second bottom surface 15b is surrounded by the first bottom surface 15a. In this case, it is easy to confirm which position the second bottom surface 15b lies at, which facilitates placing the mirror member 30 on the second bottom surface 15b. In the example illustrated in FIG. 2B, the dimension in the X direction of the second bottom surface 15b is smaller than the dimension in the X direction of the first bottom surface 15a, although the relationship between the dimensions of these bottom surfaces is not limited to this example. The dimension in the X direction of the second bottom surface 15b may be equal to the dimension in the X direction of the first bottom surface 15a. The second bottom surface 15b may be arranged so as to traverse the recessed portion 13 in the X direction. In this case, in a top view, the second bottom surface 15b may be located between a part of the first bottom surface 15a which is on the +Z direction side relative to the second bottom surface 15b and the remaining part of the first bottom surface 15a which is on the −Z direction side relative to the second bottom surface 15b. Even in this case, it is easy to confirm which position the second bottom surface 15b lies at, which facilitates placing the mirror member 30 on the second bottom surface 15b. Note that the part of the first bottom surface 15a which is on the +Z direction side relative to the second bottom surface 15b may be omitted.

In the light-emitting device 110, the second bottom surface 15b is lower than the first bottom surface 15a, so that the mirror member 30 can be disposed at a lower position as compared with the light-emitting device 100 where the second bottom surface 15b is not provided. As a result, even if the thickness of the submount 21 included in the laser light source 20 is further reduced, the laser light L emitted from the semiconductor laser element 22 can be incident on the reflective surface 32. Allowing further reduction in the thickness of the submount 21 allows the heat radiated from the semiconductor laser element 22 during operation to be more effectively transferred to the substrate 10 via the submount 21, and the heat can be more effectively transferred to the mounting surface via the substrate 10. This facilitates improvement in the heat radiation from the light-emitting device 100.

Furthermore, in the light-emitting device 110, as for the first bottom surface 15a and the second bottom surface 15b that are flat and parallel to each other, the laser light source 20 is disposed on the first bottom surface 15a while the mirror member 30 is disposed on the second bottom surface 15b. Therefore, the deviation of the traveling direction of the laser light L emitted from the laser light source 20 from the +Z direction can be reduced, and the deviation of the traveling direction of the laser light L reflected by the reflective surface 32 from the +Y direction can be reduced. As a result, the deviation of the laser light L outgoing from the light-emitting device 110 from the designed traveling direction, i.e., the +Y direction, can be reduced. When the first bottom surface 15a, the second bottom surface 15b, and the lower surface 14 are flat and parallel to one another, the deviation of the laser light L outgoing from the light-emitting device 110 from the designed traveling direction, i.e., the +Y direction, can be effectively reduced. The effects achieved by the flat lower surface 14 of the substrate 10V in the light-emitting device 110 are the same as those achieved by the flat lower surface 14 in the light-emitting device 100 of the present embodiment.

### Method of Manufacturing Light-Emitting Device

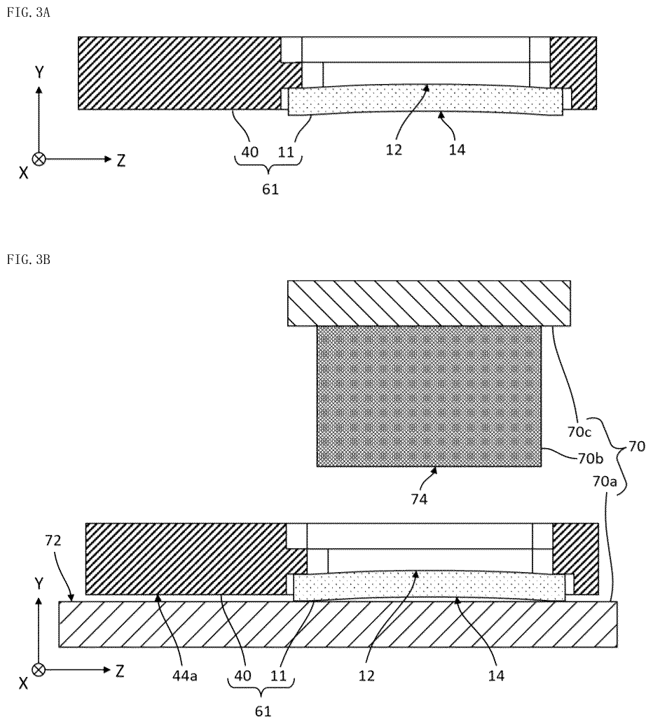

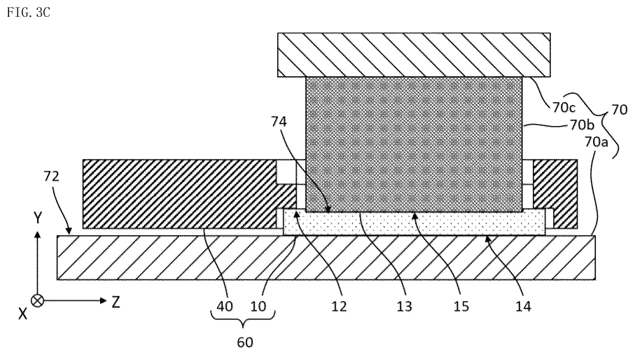

Hereinafter, a production method of the base part 60 for use in the light-emitting device 100 of the present embodiment is described with reference to FIG. 3A, FIG. 3B and FIG. 3C. FIG. 3A, FIG. 3B and FIG. 3C are cross-sectional views parallel to the YZ plane for describing an example of steps in the production method of the base part 60 for use in the light-emitting device 100 of the present embodiment.

In the first step, as illustrated in FIG. 3A, a base part main body 61 formed by bonding together the substrate 11 and the frame body 40 is provided. The substrate 11 has an upper surface 12 and a lower surface 14. The frame body 40 is positioned around the upper surface 12 of the substrate 11. The material of the substrate 11 is the same as that of the substrate 10 illustrated in FIG. 1C. The material of the frame body 40 is as described above. As described above, in bonding together the substrate 11 and the frame body 40 via an inorganic bonding material such as brazing material, if the thermal expansion coefficient of the substrate 11 is higher than the thermal expansion coefficient of the frame body 40, the substrate 11 tends to warp convexly upward in the long side direction (longitudinal direction) rather than the short side direction (transverse direction) as illustrated in FIG. 3A due to the heat applied to the inorganic bonding material.

In a subsequent step, the base part main body 61 is set in a press machine 70 as illustrated in FIG. 3B. The press machine 70 includes a stage 70a having an upper surface 72, a pressing portion 70b having a lower end 74 and elongated in the Y direction, and a support member 70c supporting the pressing portion 70b and movable along the Y direction. The upper surface 72 of the stage 70a and the lower end 74 of the pressing portion 70b are flat surfaces parallel to the XZ plane and are parallel to each other. In the base part main body 61, at least a part of the lower surface 14 of the substrate 11 is in contact with the upper surface 72 of the stage 70a. This is because the distance in the Y direction from the upper surface 12 of the substrate 11 to the lower surface 14 of the substrate 11 is longer than the distance in the Y direction from the upper surface 12 of the substrate 11 to the first lower surface 44a of the frame body 40. Herein, the distance in the Y direction from the upper surface 12 of the substrate 11 to the lower surface 14 of the substrate 11 refers to the distance in the Y direction from the highest part of the upper surface 12 of the substrate 11 to the lowest part of the lower surface 14 of the substrate 11. The distance in the Y direction from the upper surface 12 of the substrate 11 to the first lower surface 44a of the frame body 40 refers to the distance in the Y direction from the highest part of the upper surface 12 of the substrate 11 to the lowest part of the first lower surface 44a of the frame body 40.

In a subsequent step, the upper surface 12 of the substrate 11 is pressed down by the lower end 74 of the pressing portion 70b as illustrated in FIG. 3C. This pressing is carried out such that, for example, a hole in the frame body 40 in a top view is detected by image recognition, and the center of the lower end 74 of the pressing portion 70b in a bottom view is aligned with the center of the hole. As a result, a recessed portion 13 having a bottom surface 15 is formed in the upper surface 12, whereby the substrate 10 is obtained. The substrate 11 illustrated in FIG. 3B is sandwiched between the stage 70a and the pressing portion 70b, resulting in the substrate 10 illustrated in FIG. 3C. The shape of the recessed portion 13 is determined by the lower end 74 of the pressing portion 71b, and the shape of the lower surface 14 of the substrate 10 is determined by the upper surface 72 of the stage 70a. By pressing, the bottom surface 15 of the recessed portion 13 and the lower surface 14 of the substrate 10 result in flat surfaces which are parallel to the XZ plane and parallel to each other. The flatness of the bottom surface 15 of the recessed portion 13 depends on the flatness of the lower end 74 of the pressing portion 70b, and the flatness of the lower surface 14 of the substrate 10 depends on the flatness of the upper surface 72 of the stage 70a.

By the above-described pressing, a part of the upper surface 12 of the substrate 10 which does not come into contact with the lower end 74 of the pressing portion 70b is slightly raised upward, whereby an elevated portion 16 can be formed as illustrated in FIG. 1G. The elevated portion 16, allows for improving the visibility of the shape of the recessed portion 13 and, therefore, the laser light source 20 and the mirror member 30 can be easily placed on the bottom surface 15 of the recessed portion 13.

Through the above-described steps, the base part 60 for use in the light-emitting device 100 of the present embodiment can be produced. The manufacturing method of the light-emitting device 100 of the present embodiment includes, in addition to the above-described production steps of the base part 60, the step of placing the laser light source 20 on the bottom surface 15 of the recessed portion 13, more specifically placing the semiconductor laser element 22 on the bottom surface 15 of the recessed portion 13 with the submount 21 interposed therebetween, as illustrated in FIG. 1F. The manufacturing method further includes the step of placing the mirror member 30 on the bottom surface 15 of the recessed portion 13 as illustrated in FIG. 1F. When, in place of the laser light source 20, a surface-emitting semiconductor laser element that is configured to emit a laser light L in the +Y direction is disposed on the bottom surface 15, the step of placing the mirror member 30 can be omitted.

By the above-described simple process of forming the recessed portion 13 in the upper surface 12 of the substrate 10 using the press machine 70, the bottom surface 15 of the recessed portion 13 results in a flat surface. As a result, as previously described, the lower surface of the submount 21 is in uniform contact with the bottom surface 15 and, therefore, the heat radiated from the semiconductor laser element 22 while the light-emitting device 100 is in operation can be effectively transferred to the substrate 10 via the submount 21. This facilitates improvement in the heat radiation from the light-emitting device 100.

Furthermore, by the above-described simple process of forming the recessed portion 13 in the upper surface 12 of the substrate 10 using the press machine 70, the lower surface 14 of the substrate 10 results in a flat surface. Accordingly, as described above, in the case of disposing the light-emitting device 100 on the flat mounting surface, the entirety of the lower surface 14 of the substrate 10 is in uniform contact with the mounting surface via the bonding material and, therefore, the heat radiated from the semiconductor laser element 22 during operation can be effectively transferred to the mounting surface via the substrate 10. This facilitates improvement in the heat radiation from the light-emitting device 100.

Furthermore, with the laser light source 20 and the mirror member 30 disposed on the flat bottom surface 15 of the recessed portion 13, the deviation of the traveling direction of the laser light L outgoing from the light-emitting device 100 from the designed traveling direction can be reduced as previously described.

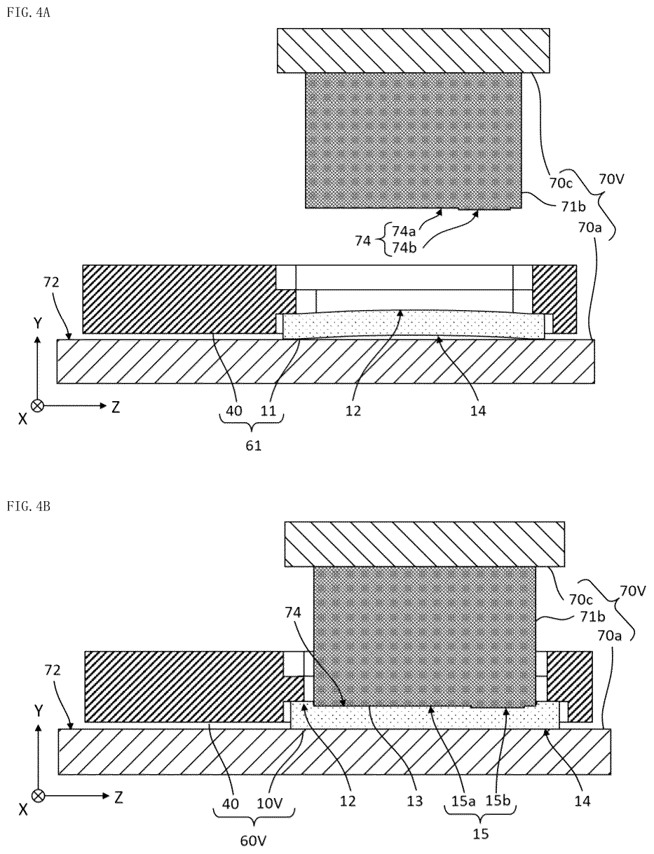

Next, a production method of the base part 60V for use in a variation example of the light-emitting device 100 of the present embodiment is described with reference to FIG. 4A and FIG. 4B. FIG. 4A and FIG. 4B are cross-sectional views parallel to the YZ plane for describing an example of steps in the production method of the base part 60V for use in the variation example of the light-emitting device 100 of the present embodiment.

In a step subsequent to providing the above-described base part main body 61, the base part main body 61 is set in a press machine 70V as illustrated in FIG. 4A. The press machine 70V includes a pressing portion 71b in place of the pressing portion 70b illustrated in FIG. 3B. The lower end 74 of the pressing portion 71b includes the first lower end 74a and the second lower end 74b. With respect to the upper surface 72 of the stage 70a, the second lower end 74b is at a position lower than the first lower end 74a. The upper surface 72 of the stage 70a and the first lower end 74a and the second lower end 74b of the pressing portion 70b are flat surfaces parallel to the XZ plane and are parallel to one another. The dimension in the X direction of the second lower end 74b may be smaller than the dimension in the X direction of the first lower end 74a, and the second lower end 74b may be surrounded by the first lower end 74a in a bottom view. Alternatively, the dimension in the X direction of the second lower end 74b may be equal to the dimension in the X direction of the first lower end 74a and, in a bottom view, the second lower end 74b may be located between a part of the first lower end 74a which is on the +Z direction side relative to the second lower end 74b and the remaining part of the first lower end 74a which is on the −Z direction side relative to the second lower end 74b.

In a subsequent step, as illustrated in FIG. 4B, in the press machine 70V, the upper surface 12 of the substrate 11 is pressed down by the lower end 74 of the pressing portion 71b. As a result, the substrate 10V that has the recessed portion 13 formed in the upper surface 12 is obtained. The shape of the recessed portion 13 is determined by the shape of the lower end 74 of the pressing portion 71b. The bottom surface 15 of the recessed portion 13 includes the first bottom surface 15a and the second bottom surface 15b. With respect to the lower surface 14 of the substrate 10V, the second bottom surface 15b is at a position lower than the first bottom surface 15a. By pressing, the first bottom surface 15a and the second bottom surface 15b of the recessed portion 13 and the lower surface 14 of the substrate 10V result in flat surfaces which are parallel to the XZ plane and parallel to one another. The flatness of the first bottom surface 15a of the recessed portion 13 depends on the flatness of the first lower end 74a of the pressing portion 70b, and the flatness of the second bottom surface 15b of the recessed portion 13 depends on the flatness of the second lower end 74b of the pressing portion 70b. The flatness of the lower surface 14 of the substrate 10V also depends on the flatness of the upper surface 72 of the stage 70a, as does the flatness of the lower surface 14 of the substrate 10 illustrated in FIG. 3B.

Through the above-described process, the base part 60V for use in the variation example of the light-emitting device 100 of the present embodiment can be produced. Note that, after the base part 60 for use in the light-emitting device 100 of the present embodiment is produced, the bottom surface 15 of the recessed portion 13 may be partially pressed down by another pressing portion. As a result of the pressing, the bottom surface 15 has the first bottom surface 15a and the second bottom surface 15b and, thus, the base part 60V for use in the variation example of the light-emitting device 100 of the present embodiment is obtained.

The manufacturing method of the variation example of the light-emitting device 100 of the present embodiment includes, in addition to the above-described process of producing the base part 60V, the step of placing the laser light source 20 on the bottom surface 15 of the recessed portion 13, more specifically on the first bottom surface 15a, as illustrated in FIG. 2A. The manufacturing method of the variation example of the light-emitting device 100 of the present embodiment further includes the step of placing the mirror member 30 on the bottom surface 15 of the recessed portion 13, more specifically on the second bottom surface 15b, as illustrated in FIG. 2A.

By the above-described simple step of forming the recessed portion 13 in the upper surface 12 of the substrate 10 using the press machine 70, the first bottom surface 15a and the second bottom surface 15b, which are flat surfaces at different heights, are obtained. With respect to the lower surface 14 of the substrate 10V, the laser light source 20 is disposed on the first bottom surface 15a that is relatively high, while the mirror member 30 is disposed on the second bottom surface 15b that is relatively low. As a result, as described above, the thickness of the submount 21 can be further reduced and, therefore, the heat radiated from the semiconductor laser element 22 during operation can be more effectively transferred to the substrate 10 via the submount 21. This facilitates improvement in the heat radiation from the light-emitting device 100.

Furthermore, as for the first bottom surface 15a and the second bottom surface 15b that are flat and parallel to each other, the laser light source 20 is disposed on the first bottom surface 15a while the mirror member 30 is disposed on the second bottom surface 15b. Thus, as previously described, the deviation of the traveling direction of the laser light L outgoing from the light-emitting device 100 from the designed traveling direction can be reduced.

A light-emitting device of the present disclosure can be used in, for example, devices such as laser processing machines, projectors, and light sources for lighting devices.

What is claimed is:

1. A light-emitting device comprising:
a substrate having an upper surface, the upper surface including a recessed portion, the recessed portion having a bottom surface including a flat region, the substrate being made of a metal material;
a submount disposed on the bottom surface of the recessed portion;
a semiconductor laser element disposed on the submount, the semiconductor laser element being configured to emit a laser light;
a lens support member disposed on the submount;
a lens supported by the lens support member, the lens being configured to collimate or converge the laser light emitted from the semiconductor laser element; and
a frame body surrounding the semiconductor laser element in a top view, the frame body being made of a ceramic material,
wherein, in the top view, each of the substrate and the semiconductor laser element has a rectangular shape, the rectangular shape having long sides and short sides, and
the long sides of the substrate and the long sides of the semiconductor laser element are parallel to one another.

2. The light-emitting device of claim 1, wherein a length of each of the long sides of the semiconductor laser element is equal to or greater than 1500 μm.

3. The light-emitting device of claim 1 wherein, in the top view, the recessed portion has a rectangular shape with rounded corners.

4. The light-emitting device of claim 1, wherein the substrate has a flat lower surface located opposite to the upper surface.

5. The light-emitting device of claim 1, further comprising
a mirror member disposed on the bottom surface of the recessed portion, the mirror member being configured to reflect the laser light to change a traveling direction of the laser light into a direction away from the upper surface of the substrate.

6. The light-emitting device of claim 1 wherein, in the top view, an outer edge of the recessed portion is located inward of the frame body.

7. The light-emitting device of claim 4, wherein the bottom surface of the recessed portion and the lower surface of the substrate are parallel to each other.

8. The light-emitting device of claim 1, wherein a distance between the upper surface of the substrate and the bottom surface of the recessed portion is smaller than a distance between an upper surface of the semiconductor laser element and the bottom surface of the recessed portion.

9. The light-emitting device of claim 1, wherein a distance between the upper surface of the substrate and the bottom surface of the recessed portion is smaller than a distance between an upper surface of the semiconductor laser element and a lower surface of the semiconductor laser element.

10. The light-emitting device of claim 4, wherein
a flatness of the flat region in the bottom surface of the recessed portion is equal to or smaller than 10 μm, and
a flatness of the lower surface of the substrate is equal to or smaller than 50 μm.

11. The light-emitting device of claim 5, wherein
the bottom surface of the recessed portion includes a first bottom surface supporting the semiconductor laser element and a second bottom surface supporting the mirror member, and
a distance between the lower surface of the substrate and the first bottom surface is longer than a distance between the lower surface of the substrate and the second bottom surface.

12. The light-emitting device of claim 11, wherein a distance between the upper surface of the substrate and the lower surface of the substrate is longer than a distance between the upper surface of the substrate and a lower surface of the frame body.

13. The light-emitting device of claim 11, wherein the first bottom surface and the second bottom surface are flat and parallel to each other.

14. The light-emitting device of claim 1, wherein a distance between the upper surface of the substrate and the lower surface of the substrate is longer than a distance between the upper surface of the substrate and a lower surface of the frame body.

15. The light-emitting device of claim 1, wherein
the frame body has an inner lateral surface defining an opening extending from an upper surface of the frame body to a lower surface of the frame body, the inner lateral surface defining a stepped portion on a lower surface side of the opening, and
a peripheral region of the upper surface of the substrate is bonded to the stepped portion.

16. The light-emitting device of claim 15, wherein the peripheral region of the upper surface of the substrate and the step portion are bonded together via an inorganic bonding material.
